(19) United States
(12) Patent Application Publication
(10) Pub. No.: US 2024/0376294 A1
(43) Pub. Date: Nov. 14, 2024

(54) THERMALLY CONDUCTIVE COMPOSITION

(71) Applicant: Sumitomo Chemical Co., Ltd., Tokyo (JP)

(72) Inventors: Thomas Fletcher, Godmanchester (GB); Simon King, Godmanchester (GB)

(73) Assignee: Sumitomo Chemical Co., Ltd., Tokyo (JP)

(21) Appl. No.: 18/284,850

(22) PCT Filed: Mar. 30, 2022
(86) PCT No.: PCT/EP2022/058392

§ 371 Date: Sep. 28, 2023

(30) Foreign Application Priority Data
Mar. 30, 2021 (GB) 2104546.3

(51) Int. Cl. C08K 9/04; C08L 79/02; H01L 23/00; H01L 23/373; H01L 25/065

(52) U.S. Cl. CPC C08K 9/04; C08L 79/02; H01L 23/3737; H01L 24/29; H01L 24/32; C08K 2201/001; H01L 25/0657; H01L 2224/2929; H01L 2224/29387; H01L 2224/32225; H01L 2225/06517; H01L 2225/06541; H01L 2225/06589; H01L 2924/16235

(57) ABSTRACT

A composition comprising a conjugated polymer and thermally conductive flakes. A thermally conductive film may be formed from the composition. The film may be used in an electronic device, for example as an underfill.

### BACKGROUND

Thermally conductive materials are used in a wide variety of applications including in underfill for flip-chips to reduce thermally induced stresses following application of a flip chip.

Mary Liu and Wusheng Yin, “A novel high thermal conductive underfill for flip chip application” http://yincae.com/assets/wp-1000-03_2013.pdf discloses an underfill containing diamond powder.

Islam et al, “Enhanced Thermal Conductivity of Liquid Crystalline Epoxy Resin using Controlled Linear Polymerization”, ACS Macro Lett. 2018, 7, 10, 1180-1185discloses liquid crystalline epoxy resin with a 2-D boron nitride filler.

JP2009292907discloses a resin composition comprising poly (p-phenylene vinylene) resin and a boron nitride nanotube.

CN110272614 discloses a composite heat-conducting polymer material comprising a polymer matrix material and a heat-conducting filler which is surface-modified with a pi-conjugated polymer.

### SUMMARY

In some embodiments, the present disclosure provides a composition comprising a conjugated polymer and thermally conductive flakes.

Optionally, the thermally conductive flakes comprise boron nitride.

Optionally, the thermally conductive flakes have a mean average aspect ratio of at least 10:1.

Optionally, the thermally conductive flakes comprise an organic molecule bound to the particle surface.

Optionally, the thermally conductive flakes make up 1-60% of the weight of the conductive particle+conjugated polymer weight.

Optionally, the conjugated polymer comprises a repeating structure of formula (II):

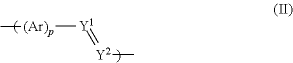

wherein Ar in each occurrence is an arylene or heteroarylene group which is unsubstituted or substituted with one or more substituents; p is at least 1; one of Y¹ and Y² is CR⁷ wherein R⁷is H or a substituent; and the other of Y¹ and Y² is N.

In some embodiments, the present disclosure provides a film comprising a composition as described herein.

Optionally, the film is crosslinked.

In some embodiments, the present disclosure provides an electronic device comprising a film according as described herein disposed on a functional layer thereof.

Optionally, the film is disposed in a region between the surface of the functional layer and a first surface of a first chip electrically connected to the functional layer.

Optionally, the functional layer is a printed circuit board; an interposer; or a second chip.

Optionally, the electronic device comprises a 3D chip stack.

In some embodiments, the present disclosure provides a heat sink comprising a first surface having fins extending therefrom and an opposing second surface having a film as described herein.

In some embodiments, the present disclosure provides a formulation comprising a composition as described herein and a solvent or solvent mixture wherein the polymer is dissolved in the solvent and the thermally conductive particles are dispersed in the solvent or solvent mixture.

In some embodiments, the present disclosure provides a method of forming a film as described herein, comprising deposition of the formulation as described herein onto a surface and evaporating the one or more solvents.

### DESCRIPTION OF DRAWINGS

FIG. 1 illustrates a polythiophene polymer;

FIG. 2 schematically illustrates bonding between polymer chains;

FIG. 3 schematically illustrates an electronic device according to some embodiments comprising a flip-chip electrically connected to a substrate;

FIG. 4A schematically illustrates a method according to some embodiments of forming the electronic device of FIG. 3 in which an underfill layer is formed between the substrate and the flip-chip;

FIG. 4B schematically illustrates a method according to some embodiments of forming the electronic device of FIG. 3 in which a non-conducting film is applied to the flip chip prior to connection to the substrate;

FIG. 5 schematically illustrates a 3D chip stack according to some embodiments;

FIG. 6 schematically illustrates a substrate for measurement of thermal conductivity of a film;

FIGS. 7A and 7B schematically illustrate apparatus for measurement of thermal conductivity including the substrate of FIG. 6;

FIG. 8 is a graph of thermal conductivity vs. thermally conducting loading for a matrix containing spherical and flake-like thermally-conducting particles;

FIG. 9 is a graph of thermal conductivity vs. thermally conducting particle loading for compositions according to embodiments of the disclosure and comparative compositions at a particle loading of up to about 20%; and

FIG. 10 is a graph of thermal conductivity vs. thermally conducting particle loading for compositions according to embodiments of the disclosure and comparative compositions at a particle loading of up to about 55%.

The drawings are not drawn to scale and have various viewpoints and perspectives. The drawings are some implementations and examples. Additionally, some components and/or operations may be separated into different blocks or combined into a single block for the purposes of discussion of some of the embodiments of the disclosed technology. Moreover, while the technology is amenable to various modifications and alternative forms, specific embodiments have been shown by way of example in the drawings and are described in detail below. The intention, however, is not to limit the technology to the particular implementations described. On the contrary, the technology is intended to cover all modifications, equivalents, and alternatives falling within the scope of the technology as defined by the appended claims.

### DETAILED DESCRIPTION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list. References to a layer “over” another layer when used in this application means that the layers may be in direct contact or one or more intervening layers are may be present. References to a layer “on” another layer when used in this application means that the layers are in direct contact.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms.

In the following description, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list. References to a layer “over” another layer when used in this application means that the layers may be in direct contact or one or more intervening layers are may be present. References to a layer “on” another layer when used in this application means that the layers are in direct contact.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms.

In the following description, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

The present inventors have found that a composition comprising or consisting of thermally conductive flake filler dispersed in a conjugated polymer may provide high thermal conductivity, even at relatively low loading of the filler. The composition may be deposited from a formulation in which the conjugated polymer is dissolved and the filler particles are dispersed. Optionally, thermal conductivity of compositions as described herein is at least 0.5 Wm⁻¹K⁻¹, optionally at least 1 Wm⁻¹K⁻¹.

### Polymer

The conjugated polymer as described herein has a backbone comprising arylene or heteroarylene groups which are conjugated together in the polymer backbone. The arylene or heteroarylene groups may be directly linked or may be linked by a conjugating group, for example a carbon-carbon double bond (alkene) group or a carbon-nitrogen double bond (imine) group. The conjugation may extend across the whole of the polymer backbone or the polymer backbone may comprise conjugated regions interrupted by non-conjugating repeat units.

The polymers may be substituted with groups for bonding together of polymer chains, e.g. hydrogen bonding or covalent bonding, to enhance long-range ordering of the polymers.

Polymers as described herein are preferably at least partially crystalline.

Polymers as described herein may undergo pi-pi stacking when deposited as a film.

Optionally, thermal conductivity of polymers as described herein is at least 0.15 Wm⁻¹K⁻¹, optionally at least 0.2 or 0.3 Wm⁻¹K⁻¹.

In some embodiments, the conjugated polymer is formed by crosslinking of oligomers.

The oligomers may be substituted with groups for bonding together of oligomer chains, e.g. hydrogen bonding or covalent bonding, to enhance long-range ordering of the oligomers.

Oligomers as described herein are preferably at least partially crystalline.

Oligomers as described herein preferably comprise an arylene or heteroarylene group which may be unsubstituted or substituted with one or more substituents.

Oligomers as described herein may undergo pi-pi stacking when deposited as a film.

Oligomers as described herein may have formula (I):

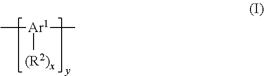

wherein Ar¹ is an arylene or heteroarylene; y is at least 2; R¹ in each occurrence is independently H or a substituent; R² in each occurrence is independently H or a substituent; and x is 0 or a positive integer.

Optionally, y is 2-10.

Optionally, x is 0, 1, 2, 3 or 4.

Ar¹ may be a C₆₋₂₀ arylene or a 5-20 membered heteroarylene.

Ar¹ may be a monocyclic or polycyclic arylene or heteroarylene.

In some embodiments, each Ar¹ is the same.

In some embodiments, the oligomer contains two or more different Ar¹ groups. According to these embodiments, the oligomer preferably contains two different Ar¹ groups (A and B) in an alternating (ABAB . . . ) arrangement.

Exemplary Ar¹ groups include, without limitation, para-phenylene, thiophene, furan, benzobisoxazole, and combinations thereof. Exemplary oligomers include oligo-p-phenylene; oligothiophene; and oligo-(phenylene benzobisoxazole).

Preferably, Ar¹ groups are linked through aromatic carbon bonds.

Preferably, the oligomer is a rigid rod oligomer.

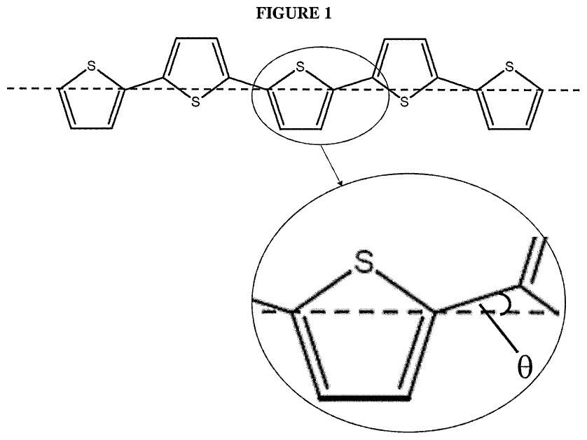

A rigid rod oligomer as described herein may have a structure in which a notional straight line can be drawn through each Ar¹ group of the oligomer, as illustrated in FIG. 1.

Optionally, each bond angle θ between the notional straight line and each bond of Ar¹ to an adjacent repeat unit is no more than 45 degrees.

The number and identity of R¹ and R² groups may be selected according to the desired solubility and/or reactivity of the oligomers.

Optionally, R¹ is selected from the group consisting of:
H;
F;
CN;
NO₂;
branched, linear or cyclic C₁₋₂₀ alkyl wherein one or more non-adjacent C-atoms may be replaced with O, S, NR³, SiR₄², C═O OR COO; wherein R³ in each occurrence is H or a substituent, preferably H “or a C₁₋₂₀ hydrocarbyl group and R⁴ in each occurrence is independently a substituent, optionally a C¹⁻²⁰ hydrocarbyl group;
an aryl or heteroaryl group Ar³ which is unsubstituted or substituted with one or more substituents; and
a reactive group comprising a first reactive moiety X¹ and a second reactive moiety X² wherein moieties X¹ and X² are capable of reacting to form a covalent bond.

Exemplary hydrocarbyl groups R³ and R⁴ include, without limitation, C₁₋₂₀ alkyl; unsubstituted phenyl; and phenyl substituted with one or more C₁₋₁₂ alkyl groups.

Substituents of Ar³, where present, may be selected from C₁₋₂₀ alkyl wherein one or more non-adjacent C-atoms may be replaced with O, S, NR³ or SiR⁴ ₂.

Optionally, R² is selected from the groups described with respect to R¹ with the exclusion of H.

R¹ and/or R² groups may be selected so as to cause binding between R¹ groups of different oligomer chains; between R¹ and R² groups of different oligomer chains; and/or between R² groups of different oligomer chains.

Preferably, the same R¹ groups and/or the same R² groups of different oligomer chains are capable of forming a bond.

In some embodiments, the oligomer comprises R¹ and/or R² groups, preferably R² groups, which are capable of forming a hydrogen bond between oligomer chains.

Groups capable of hydrogen bonding include groups with an NH or OH group, for example groups of formulae -Sp-OH or -Sp-NHR³ wherein Sp is a flexible spacer group, e.g. an alkylene chain or a phenylene-alkylene chain, and R³ is H or a substituent.

In some embodiments, the oligomer comprises R¹ and/or R² groups, preferably R² groups, which are capable of forming a covalent bond between oligomer chains.

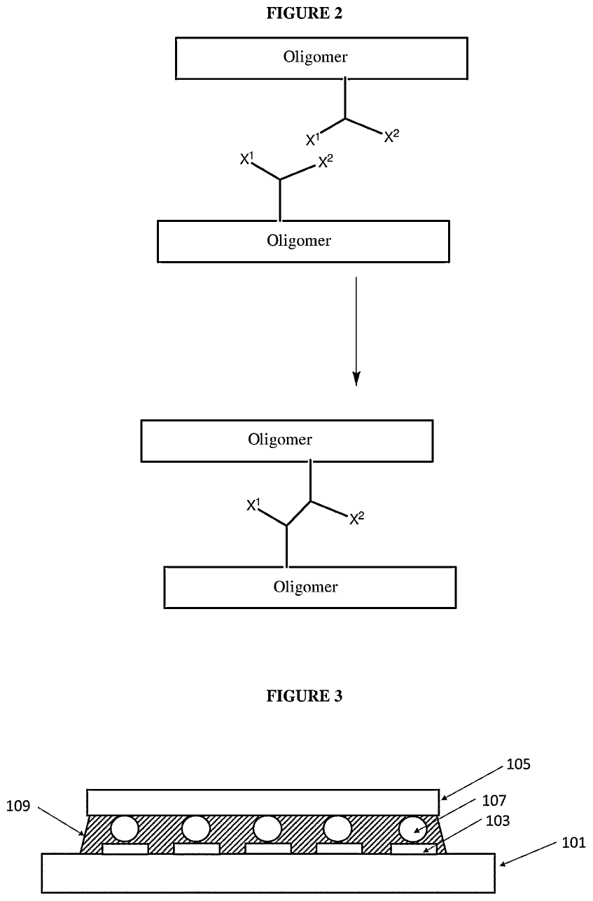

FIG. 2 schematically illustrates oligomer chains substituted with a substituent containing both reactive groups X¹ and X² wherein X¹ and X² are capable of reacting with one another to form a covalent bond. An X¹ group of one oligomer chain may react with an X² of another oligomer chain, leaving one unreacted X¹ group and one unreacted X² group.

The unreacted X¹ and X² groups may react with X¹ and X² groups of further oligomer chains, thereby creating a crosslinked oligomer.

X¹ and X² groups on different oligomer chains may initially hydrogen bond before reacting to create a crosslinked structure.

In some embodiments, X¹ is a group comprising a quinone and X² is a group comprising a diamine. The quinone and diamine groups may react to form an imide as per Scheme 1:

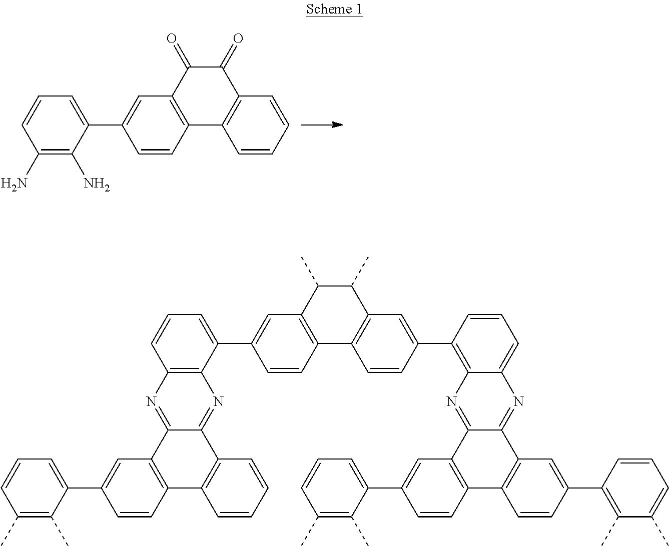

It will be appreciated that a wide range of X¹ and X² groups which are capable of reacting to form a covalent bond are known to the skilled person including, without limitation, groups which undergo an elimination, substitution or cycloaddition reaction.

In some embodiments, the conjugated polymer comprises a repeating structure of formula (II):

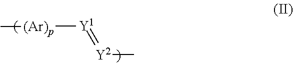

wherein Ar in each occurrence is an arylene or heteroarylene group which is unsubstituted or substituted with one or more substituents; p is at least 1; one of Y¹ and Y² is CR⁷ wherein R⁷ is H or a substituent; and the other of Y¹ and Y² is N.
p is preferably at least 2, optionally 2-5. The extended rigid-rod type structure of formula (II) may enhance thermal conductivity of the polymer as compared to the case where p=1.
Ar in each occurrence in (Ar)p may be the same or different, preferably the same.

Exemplary Ar groups include, without limitation, para-phenylene, thiophene, furan, and benzobisoxazole, each of which may independently be unsubstituted or substituted with one or more substituents. Para-phenylene is preferred.

R⁷ is preferably H or a C₁₋₂₀ hydrocarbyl group, more preferably H.

A C₁₋₂₀ hydrocarbyl group as described anywhere herein is preferably selected from C₁₋₂₀ alkyl; unsubstituted phenyl; and phenyl substituted with one or more C₁₋₁₂ alkyl groups.

Optionally, one or more Ar groups of (Ar) p are substituted with one or more substituents. Preferably, substituents are selected from substituents R⁸ wherein R⁸ in each occurrence is independently selected from:
F;
CN;
NO₂;
branched, linear or cyclic C₁₋₂₀ alkyl wherein one or more non-adjacent C-atoms may be replaced with O, S, NR³, SiR₄², C═O OR COO; wherein R³ in each occurrence is H or a substituent, preferably H or a C₁₋₂₀ hydrocarbyl group and R⁴ in each occurrence is independently a substituent, optionally a C₁₋₂₀ hydrocarbyl group;
an aryl or heteroaryl group Ar³ which is unsubstituted or substituted with one or more substituents. Optional substituents of Ar³, where present, are described above.

Preferably, at least one substituent R⁸, optionally each substituent R⁸, is C₁₋₂₀ alkyl or C₁₋₂₀ alkoxy, more preferably a C₁₋₁₂ alkyl or C₁₋₁₂ alkoxy.

The polymer may comprise a divalent linker group L disposed in the polymer backbone, wherein L is selected from O, S, NR³ or a C₁₋₁₂ alkylene group wherein one or more non-adjacent C atoms of a C₂₋₁₂ alkylene group may be replaced with O, S, NR⁵, SiR⁴ ₂, CO or COO.

In some embodiments, the divalent linker group L is disposed between and linked directly to two Ar groups.

In some embodiments, the divalent linker group L is disposed between and linked directly to an Ar group and an imine (—C(R⁷)═N—) group.

In some embodiments, the divalent linker group L is disposed between and linked directly to two imine (—C(R⁷)═N—) groups.

The polymer may be formed by polymerising a monomer or monomers having reactive groups which react to form an imine. The repeating structure of formula (II) may be part of a larger repeat unit of the polymer formed by polymerising the monomer or monomers. Exemplary repeat units include, without limitation, formulae (III)-(V):

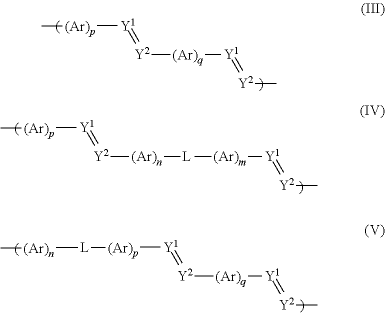

wherein Ar, p, Y¹, Y² and L are as described above;
q is at least 1, preferably 1-5, more preferably 1-3;
n is 0or a positive integer, preferably 0 or 1-5, more preferably 0, 1, 2 or 3; and
m is 0 or a positive integer, preferably 0 or 1-5, more preferably 0, 1, 2 or 3.

In each of formulae (III)-(V), it will be understood that the two Y¹ groups may both be the same one of CR⁷ and N; or one Y¹ is CR⁷ and the other Y¹ is N. Likewise, the two Y² groups may both be the same one of CR⁷ and N; or one Y² is CR⁷ and the other Y² is N. In a preferred embodiment, one Y¹ is CR⁷ and the other Y¹ is N and, accordingly, one Y² is CR⁷ and the other Y² is N.

If q is greater than 1 then each Ar of (Ar)q, may be the same or different, preferably the same.

If n is greater than 1 then each Ar of (Ar)n, may be the same or different, preferably the same.

If m is greater than 1 then each Ar of (Ar)m, may be the same or different, preferably the same.

Preferred Ar groups of (Ar)q, (Ar)m and (Ar)m are as described with reference to (Ar)p.

The repeat units of the polymer may be the same or different. In some embodiments, the polymer contains a mixture of different repeat units of formulae (III)-(V). The polymer may contain one or more of: different repeat units of formula (III); different repeat units of formula (IV); different repeat units of formula (V); and a repeat unit selected from one of formulae (III)-(V) and at least one other repeat unit selected from another of formulae (III)-(V). In a preferred embodiment, the polymer contains a repeat unit without a divalent linker group L and a repeat unit with a divalent linker group L, for example a repeat unit of formula (III) and a repeat unit of formula (IV).

In the case where n and m are each 0, the repeat unit of formula (IV) has formula (IVa):

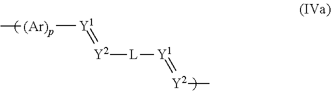

The polystyrene-equivalent number-average molecular weight (Mn) measured by gel permeation chromatography of the polymers described herein may be in the range of about 1×10³ to 1×10⁸, and preferably 1×10⁴ to 5×10⁶. The polystyrene-equivalent weight-average molecular weight (Mw) of the polymers described herein may be 1×10³ to 1×10⁸, and preferably 1×10⁴ to 1×10⁷.

Conjugated polymers comprising a repeating structure of formula (II) may be formed by polymerising a monomer or monomers having reactive groups which react to form an imine.

In some embodiments, polymers comprising a repeating structure of formula (II) are formed by polymerisation of a first monomer comprising a group of formula (II) and two reactive groups X¹ with a second monomer comprising two reactive groups X² wherein one of X¹ and X² is a group of formula-C(═O)R⁷ and the other of X¹ and X² is NH₂.

### Filler

A thermally conductive filler as described herein preferably has a thermal conductivity of at least 10 Wm ⁻¹K⁻¹. A thermally conductive filler as described herein may be electrically insulating, e.g. having an electrical conductivity of no more than 10⁻⁸ S/m, optionally no more than 10⁻⁹ S/m or 10⁻¹⁰ S/m. A thermally conductive filler as described herein may be electrically conducting.

Thermally conductive fillers include, without limitation, boron nitride; aluminium oxide, aluminium nitride, zinc oxide, carbon fibre, graphite, copper, aluminium, carbon nanotubes, and diamond. Boron nitride is preferred.

In some embodiments, the particles are particles of a single material.

In some embodiments, the surface of the particles is modified. The surface may be modified by attachment of a material comprising one or more groups selected from C₁₋₂₀ alkyl groups aromatic groups, preferably an aromatic group, for example an oligo-(hetero) arylene comprising 1-10 arylene or heteroarylene groups, or a poly-(hetero) arylene. An exemplary surface group is an oligophenylene, for example biphenyl or terphenyl.

A surface group may be bound to the particle surface by reaction of the unmodified particle with compound comprising the surface group substituted with a reactive group. The reactive group may be an aldehyde, carboxylic acid or carboxylic ester.

Preferably, the weight of the thermally conductive particles as a proportion of the thermally conductive particle+polymer weight is less than or equal to 60%, preferably 1-60%. Optionally, the amount of thermally conductive particles is below a percolation threshold of the composition.

Filler flake particles as described herein are not tubular, i.e. the flakes do not have an aperture extending through a length of the particles.

Filler flake particles as described herein may have a largest dimension of up to 100 microns. Filler flake particles as described herein may have a mean average largest dimension of up to 100 microns. Flakes as described herein preferably have a mean average aspect ratio of at least 10:1.

The aspect ratio of a particle having a length, width and thickness is a ratio of the length to thickness of the particle. A mean average aspect ratio as described herein may be determined from measurement of dimensions of a plurality of particles (e.g. at least 10 particles) in a scanning electron micrograph image of a sample of the particles.

Flakes may be formed by exfoliation using methods known to the skilled person, e.g. ultrasonication and/or ball milling.

The high aspect ratio of flakes may provide higher thermal conductivity at a given particle loading of the composition as compared to particles having a lower aspect ratio. High aspect ratio particles may therefore provide high thermal conductivity at low particle loading.

### Film Formation

The polymers of Formula (I) described herein are preferably soluble. An polymer of Formula (I) preferably has a solubility of at least 0.1 mg/ml, optionally at least 0.5 mg/ml or at least 1 mg/ml in xylene at 50° C. and at atmospheric pressure.

In some embodiments, formation of a film may comprise deposition of a formulation comprising the polymer dissolved in a solvent or solvent mixture, the filler dispersed in the solvent or solvent mixture and any other components of the film dissolved or dispersed in the solvent or solvent mixture.

In some embodiments, formation of a film may comprise deposition of a formulation comprising monomers for forming the polymer dissolved in a solvent or solvent mixture, the filler dispersed in the solvent or solvent mixture and any other components of the film dissolved or dispersed in the solvent or solvent mixture followed by reaction of the monomers.

Formulations as described anywhere herein may be deposited by any suitable solution deposition technique including, without limitation, spin-coating, dip-coating, drop-casting, spray coating and blade coating.

The formulation may be deposited onto an alignment layer, e.g. a rubbed polyimide.

Following deposition of the formulation, the formulation may be processed during or after solvent evaporation to enhance ordering of polymer chains, e.g. by stretching or rubbing of the film.

A crosslinker, if present, may be activated following deposition of the formulation to crosslink the polymers. Activation may be by thermal treatment and/or irradiation.

Solvents may be selected according to their ability to dissolve or disperse the polymer and any other soluble components of the formulation. Exemplary solvents include, without limitation, benzene or naphthalene substituted with one or more substituents, optionally one or more substituents selected from C₁₋₁₂ alkyl, C₁₋₁₂ alkoxy, F and Cl; ethers; esters; halogenated alkanes; and mixtures thereof. Exemplary solvents include, without limitation, 1,2,4-trimethylbenzene, mesitylene, 1-methylnaphthalene, 1-chloronaphthalene, diiodomethane, anisole, and 1,2-dimethoxybenzene.

### Applications

A film comprising a polymer as described herein may be used in any known application of a thermally conductive film.

A product may comprise a first component, a second component and a thermal transfer film as described herein disposed between the first component and second component wherein, in use, a temperature gradient exists between the first component and the second component.

Preferably, the product is an electronic device or apparatus, e.g. a semiconductor package.

The film as described herein may be disposed between a surface of a heat-generating component and a heat transfer component configured to transfer heat away from the heat-generating component, such as in any known thermal interface management application.

It will be understood that in this arrangement the film is configured to transfer heat from the heat-generating component to the heat transfer component. The film preferably has a first surface in direct contact with a surface of the heat-generating component and/or a second surface opposing the first surface in direct contact with a surface of the heat transfer component.

The thermally conductive film may be electrically insulating, i.e. in use the film does not provide an electrical conduction path between any electrically conductive surfaces that it may be in contact with. Optionally, the thermally conductive film has an electrical conductivity of no more than 1×10⁻⁸ S/m, optionally 1×10⁻⁹ S/m or 1×10⁻¹⁰ S/m.

Any passive or active heat transfer component known to the skilled person may be used including, without limitation, a heat sink having a surface in contact with the film and an opposing surface comprising one or more heat-dissipating features, for example fins or a pipe or channel configured to transfer heat to a fluid flowing through the pipe or channel. The fluid may or may not undergo a phase change upon absorption of heat.

In some embodiments, e.g. where the thermally conductive film is disposed on a surface of a heat sink, the thermally conductive film is electrically isolated. By “electrically isolated” is meant that the thermally conductive film is not electrically connected, directly or through any electrically conductive surface that it may be in contact with, to an electrical power source.

In some embodiments, a film as described herein may be disposed on a surface of a heat sink opposing a surface of the heat sink having fins extending therefrom. In use, the film may be disposed between the heat sink and an electrical component.

A film comprising a polymer as described herein may be used as an electrically non-conductive film, e.g. an underfill, for a flip chip including but not limited to 3D stacked multi-chips.

FIG. 3 illustrates an electronic device comprising a chip 105; a substrate 101, e.g. a printed circuit board; and electrically conductive interconnects 107 between electrically conductive pads 103 on the surface of the substrate 101 and the chip 105. Underfill 109 comprising a composition as described herein fills the region between the chip 105 and substrate 101 and surrounds the interconnects. Optionally, the polymer of the composition is crosslinked.

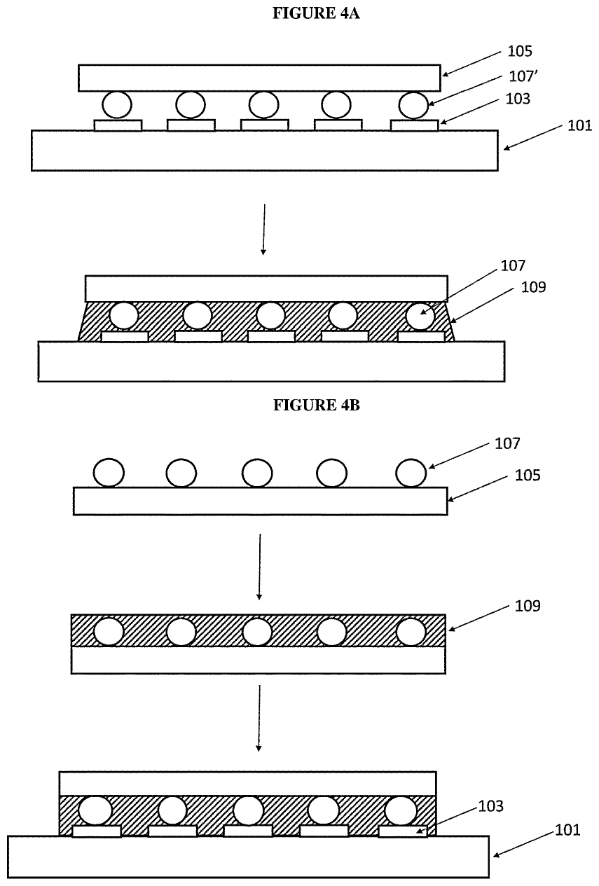

With reference to FIG. 4A, in some embodiments formation of an electronic device comprises bringing electrically conductive bumps 107′, e.g. solder bumps, into contact with electrically conductive pads 103 disposed on a substrate 101, e.g. a printed circuit board to form interconnects 107 from electrically conductive bumps 107′. Formation of underfill 109 comprising a composition as described herein comprises application of a formulation into the overlap region between the chip 105 and the substrate 101. Optionally, the polymer is crosslinked following application of the formulation, e.g. by heat and/or UV treatment.

With reference to FIG. 4B, in some embodiments a film 109 comprising the composition is applied over a surface of the chip 105 carrying electrically conductive bumps 107′. FIG. 4B illustrates complete coverage of the conductive bumps 107′ however it will be understood that the conductive bumps 107′ may be partially covered such that a part of the conductive bumps 107′ protrude from a surface of the film 109. The conductive bumps 107′ are then brought into contact with conductive pads 103 disposed on a substrate 101, e.g. a printed circuit board, to form electrically conductive interconnects between the substrate and the chip. Formation of the electrically conductive interconnects may comprise application of heat and/or pressure.

If the polymer of film 109 is crosslinked then crosslinking may take place before, during or after the conductive bumps 107′ are brought into contact with the conductive pads 103.

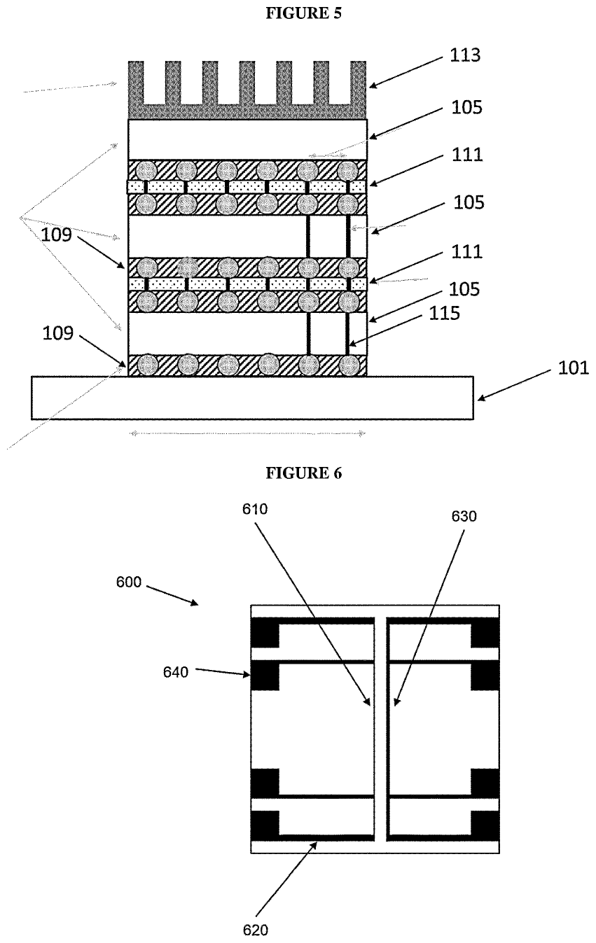

Two or more chips may be connected with a film comprising a polymer as described herein disposed between chips. FIG. 5 illustrates a 3D stack of chips 105 according to some embodiments, wherein the chips 105 are interposed by an interposer 111 and a non-electrically conductive film 109 disposed between adjacent interposer and chip surfaces and between the substrate 101, e.g. a printed circuit board, and a first chip of the 3D stack. At least one non-electrically conductive film 109 comprises a composition as described herein. Through-vias 115 are formed through the chips 105 and the interposers. The 3D stack may comprise a heat sink 113 disposed on a surface thereof.

In some embodiments, a film of a composition as described herein may be disposed between an electronic device and a heat sink.

### EXAMPLES

### Thermal Conductivity Measurement

A sensor substrate 600 (ca. 25 mm×25 mm) illustrated in FIG. 6 was used for measurement of thermal conductivity as described herein. The substrate has a polyethylene naphthalate (PEN) film (Dupont Teonex Q83, 25μm) with a 200 nm thick heating structure consisting of a 20 micron wide heater line 610, 500 micron wide busbars 620 for application of a current and contact pads 640. A sensing structure mirrors the heating structure except that the heater line is replaced with a 200 micron wide sensor line 630.

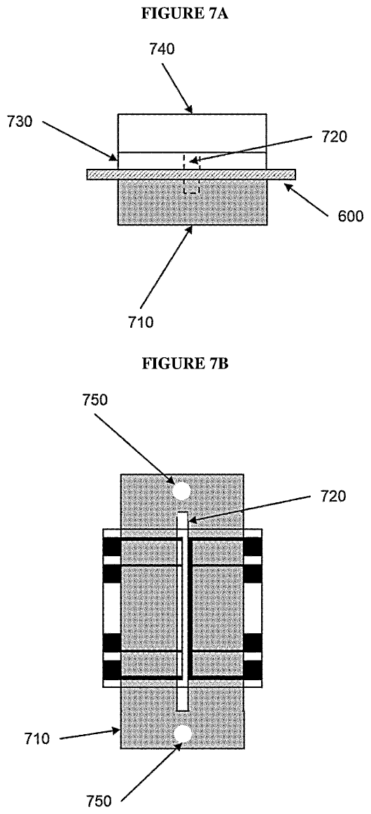

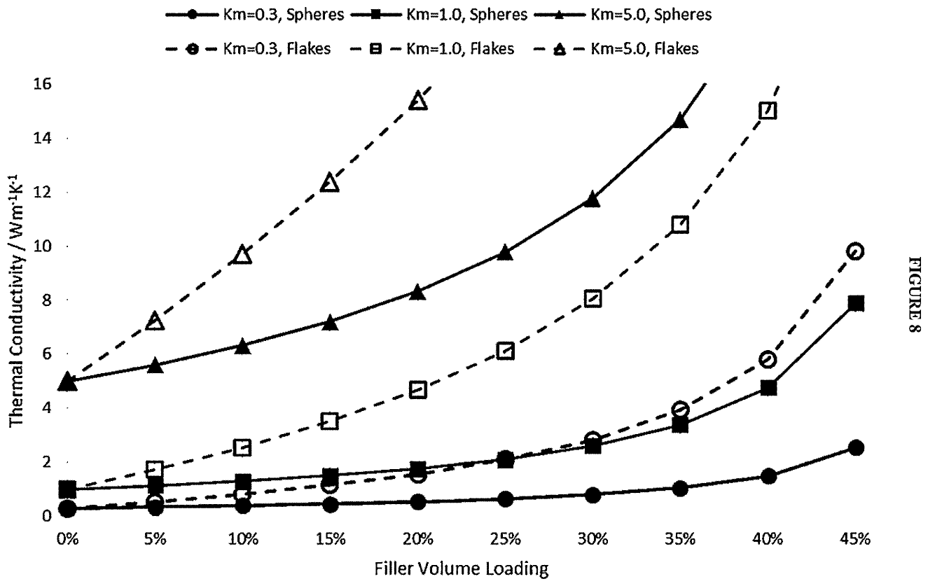

With reference to FIGS. 7A and 7B, the sensor substrate 600 carrying the film to be measured is placed on a temperature controlled aluminium block, regulated via a PID system such that the temperature may be controlled by software. The aluminium block has a long notch 720 of 1 mm width and ˜1 mm depth cut into it. The sensor substrate 600 is placed over the notch such that the central heater line 610 is aligned with the centre of the notch 720, and the sensor line 630 is aligned with the edge of the notch. A PMMA sheet 730 (2 mm thickness) with a notch cut-through matching that of the aluminium block 710 is placed over the top and an addition piece of plain PMMA sheet 740 (4 mm thickness) is placed on top to enclose the device. The entire assembly is clamped using bolts and nuts at positions 750. The heater line is connected to a sourcemeter unit (Keithley 2400) using a 4-wire measurement set up. The sensor line is connected to a multimeter unit (Keithley 2000) using a 4 wire set up.

The temperature of the assembly is first stabilised at a predetermined temperature. The resistance of the heater line and the temperature sensor is then measured. To measure the resistance of the heater line without causing undue heating a low current is sourced and voltage measured in short pulses, with time allowed between pulses for heat to be dissipated. A constant DC current is then passed along the heater line to cause resistive heating. The arrangement of the substrate in the assembly causes heat to flow through the substrate and film to the aluminium block which acts as a heat sink, setting up an approximate one dimensional steady state heat flux. The power dissipated in the heater line, and the resistance of the heater line and temperature sensor is additionally measured in this state. This process is repeated for increasing sourced current, and the complete process repeated at the next temperature setpoint.

The resistances of the heater line and sensor lines under the condition of no heat flux at different temperature setpoints are used as calibration data in a straight-line fit of resistance and temperature, allowing the temperature of the resistive elements to be determined under the condition of steady state heat flux. As such the temperature gradient, ΔT, between the heater line and temperature sensor (aligned with the heatsink) can then be calculated. The power dissipated in the heater line is assumed to be completely converted to heat energy Q. A straight line fit is then made between dT and Q with additional parameters for the length of the heater line over which power is measured (L, 14.4 mm), the distance between the voltage sense points) and the gap width (2w, 1 mm). This provides a measure of the conductance C of the device under test and is affected by losses pertaining to conductive heat transfer in the substrate and convective and radiative heat transfer to the environment (h).

To calculate a thermal conductivity κ, the same measurement process is carried out on substrates without any test film (substrate only). We assume the losses will be approximately the same when measuring a coated vs uncoated substrate. We subtract the conductance of the substrate (C_{S}) from the device measurement (C_{F+S}) to adjust for these losses. The thermal conductivity (k_{F}) is then calculated by dividing the resulting film only conductance by the film thickness (d_{F}). The film thickness is determined using a digital micrometer by measuring the total thickness and subtracting the substrate thickness.

$$C = \frac{Q w}{2 L Δ T} = κ d + 2 h {w}^{2} {κ}_{F} = \frac{{C}_{F + S} - {C}_{S}}{{d}_{F}}$$

### Filler Particle Shape

Composite thermal conductivities were calculated by the Lewis-Neilson model as disclosed in Journal of Power Technologies 95 (1) (2015) 14-24or spherical and flake-like filler particles where the matrix thermal conductivity (Km) is 0.3, 1.0 or 5.0 Wm⁻¹K⁻¹. Filler conductivity is 100 Wm⁻¹K⁻¹; maximum filler fraction is 0.52; the aspect ratio factor is 1.5 for spheres and 15 for flakes.

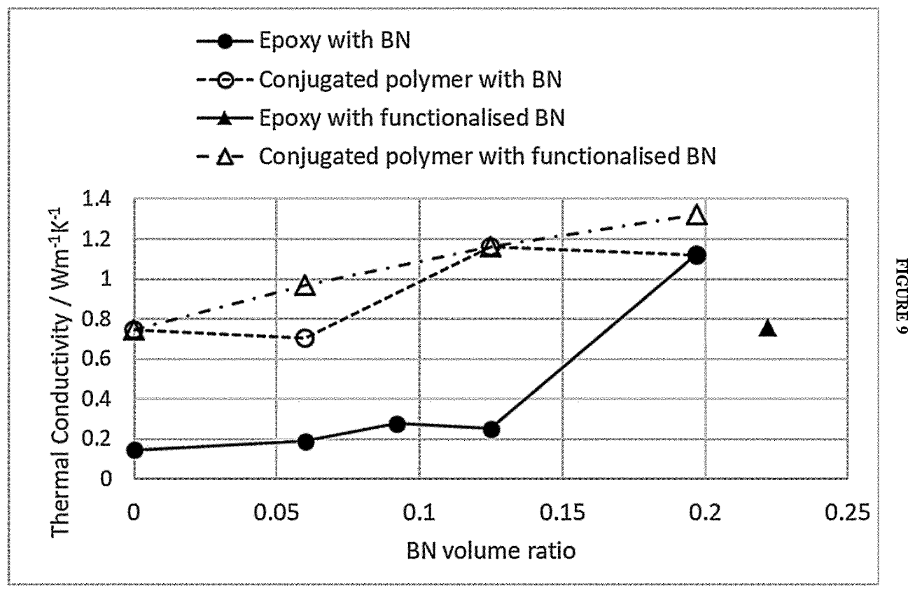

With reference to FIG. 8, thermal conductivity in each of the matrix materials is higher at a given filler volume loading for flakes as compared to spheres.

### Composite Formation (1)

Boron nitride (BN) nanoflakes were prepared via a ball milling process. BN powder (2.5 g, Goodfellow, nominal particle size 10 microns) was placed in a zirconia lined milling jar (50 mL) with zirconia milling beads (100 g, 2 mm) and 2 M NaOH (aq) (13.9 g). The mixture was milled in a planetary ball mill (Retsch PM100) at 400 rpm for 24 hrs (3×8 hours stopping overnight). On completion the mixture was decanted from the milling jar, and washed with deionised water. The milling beads were separated by sieving. The boron nitride nanoflakes were collected by filtration using a small pore filter, washing with water until the filtrate was neutral and dried under vacuum (50° C., 12hours). The product material has nominal particle size of 0.6 microns diameter and 100 nm thickness as determined via SEM analysis. This material is described herein as “non-functionalised BN”.

The milled BN was functionalized by reaction with p-terphenyl-dicarboxaldehyde. The BN was dispersed in DMSO and mass of the dicarboxaldehyde equivalent to the BN mass was added. The reaction mixture was stirred for 17 hours at 100° C. The product was collected via filtration and washed with DMSO and acetone to remove unreacted aldehyde. The attachment of the terphenyl moiety was confirmed by photoluminescence, by dispersing the product in DMSO and exciting with 270 nm light, resulting in emission at 370 nm. This material is described herein as “functionalised BN”.

A conjugated polymer was formed by polymerisation of ethylene dianiline and a terphenyl dialdehyde.

To create films of composite materials the BN was dispersed in o-dichlorobenzene at the desired concentration by grinding in a mortar followed by sonication (37 kHz, 30 minutes). The matrix material was dissolved in o-dichlorobenzene at the same concentration. Inks were prepared by volume mixing of the matrix solution and BN dispersion. Films were prepared by drop casting onto measurement substrates. Epoxy based inks were dried on a hotplate at 80° C., followed by curing at 125° C. (2 hours). Samples with the conjugated polymer matrix were dried at room temperature overnight.

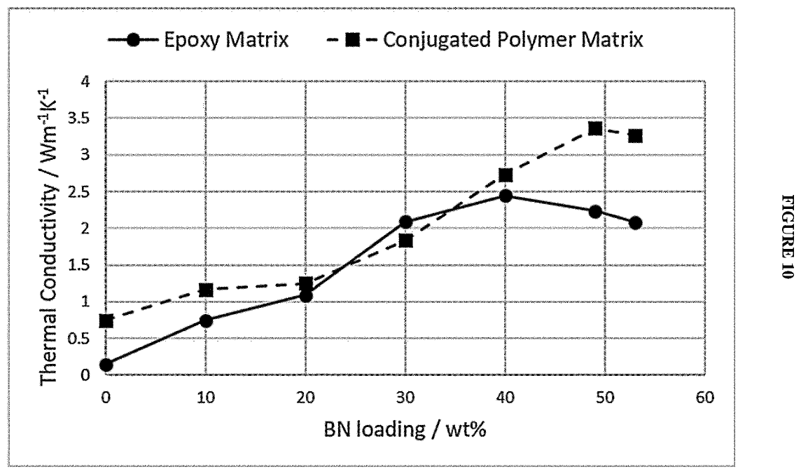

With reference to FIG. 9, increasing BN content in the composite results in increased thermal conductivity in all cases. However, in combination with a polymer as described herein, a high thermal conductivity is achieved even at low filler loadings below the percolation threshold (approximately 0.2 volume ratio) as compared to compositions with an epoxy matrix.

With reference to FIG. 10, the difference in thermal conductivity between an exemplary composition and a composition having an epoxy matrix is largest in the range above about 40% BN loading.

### Composite Formation (2)

A composite was prepared as described for Composite Formation (1) except that the functionalised BN particles had a size of 1 micron, formed using boron nitride balled milled for 6 hours. The composite contained 36 wt % of the functionalised BN particles. A film of these functionalised BN particles and a conjugated polymer as described in Composite Formation (1) had a thermal conductivity of 3.4 W/mK. Replacement of the conjugated polymer with epoxy gave a film with a thermal conductivity of 2.2 W/mK.

1. A composition comprising a conjugated polymer and thermally conductive flakes.

2. The composition according to claim 1 wherein the thermally conductive flakes comprise boron nitride.

3. The composition according to claim 1 wherein the thermally conductive flakes have a mean average aspect ratio of at least 10:1.

4. The composition according to claim 1 wherein the thermally conductive flakes comprise an organic molecule bound to the particle surface.

5. The composition according to claim 1 wherein the thermally conductive flakes make up 1-60% of the weight of the conductive particle+conjugated polymer weight.

6. The composition according to claim 1 wherein the conjugated polymer comprises a repeating structure of formula (II): 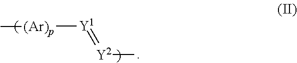
wherein Ar in each occurrence is an arylene or heteroarylene group which is unsubstituted or substituted with one or more substituents; p is at least 1; one of Y¹ and Y² is CR⁷ wherein R⁷ is H or a substituent; and the other of Y¹ and Y² is N.

7. A film comprising a composition according to claim 1.

8. The film according to claim 7 wherein the film is crosslinked.

9. An electronic device comprising a film according to claim 7 disposed on a functional layer thereof.

10. The electronic device according to claim 9 wherein the film is disposed in a region between the surface of the functional layer and a first surface of a first chip electrically connected to the functional layer.

11. The electronic device according to claim 10 wherein the functional layer is a printed circuit board; an interposer; or a second chip.

12. The electronic device according to claim 9, wherein the electronic device comprises a 3D chip stack.

13. A heat sink comprising a first surface having fins extending therefrom and an opposing second surface having a film according to claim 7 disposed thereon.

14. A formulation comprising a composition according to claim 1 and a solvent or solvent mixture wherein the polymer is dissolved in the solvent and the thermally conductive particles are dispersed in the solvent or solvent mixture.

15. A method of forming a film according to claim 7 comprising deposition of the formulation and a solvent or solvent mixture wherein the polymer is dissolved in the solvent and the thermally conductive particles are dispersed in the solvent or solvent mixture, onto a surface and evaporating the one or more solvents.
